(19) United States
(12) Patent Application Publication
(10) Pub. No.: US 2022/0026460 A1
(43) Pub. Date: Jan. 27, 2022

(54) FLOW RATE SENSOR DEVICE AND FLOW RATE SENSOR DEVICE EQUIPPED WITH COVER

(71) Applicant: KOA CORPORATION, Nagano (JP)

(72) Inventors: Yoji KOBAYASHI, Nagano (JP); Tomokazu IKENO, Nagano (JP); Yasuyuki KATASE, Nagano (JP)

(73) Assignee: KOA CORPORATION, Nagano (JP)

(21) Appl. No.: 17/421,913

(22) PCT Filed: Jan. 15, 2020
(86) PCT No.: PCT/JP2020/001112

§ 371 Date: Jul. 9, 2021

(30) Foreign Application Priority Data
Jan. 17, 2019 (JP) 2019-005735

(51) Int. Cl. G01P 5/26; G01P 5/20; G01F 1/66

(52) U.S. Cl. CPC G01P 5/26; G01F 1/661; G01P 5/20

(57) ABSTRACT

The visibility of light is improved. A flow rate sensor device includes a substrate, sensor elements electrically connected to the substrate, light emitting elements positioned in a rear part of the sensor elements and disposed on a surface of the substrate, and light-transmissive cases internally accommodating the light emitting elements between the light-transmissive cases and the substrate. The light-transmissive cases have light diffusion members projecting from ceiling sections toward the light emitting elements, the light diffusion members have light incident surfaces facing the light emitting elements and wall surfaces connecting the light incident surfaces and the ceiling sections, and at least a part of the wall surfaces has a tilting surface having a dimension between the opposing wall surfaces, the dimension gradually increasing from a side close to the light incident surface toward the ceiling section.

### TECHNICAL FIELD

The present invention relates to a flow rate sensor device and a flow rate sensor device equipped with a cover, which detects a flow rate of a fluid.

### BACKGROUND ART

Patent Literature 1 discloses an invention of an LED module which includes a light emitting element as a light source and an optical element and which increases a utilization efficiency of light from the light source by extracting light radiated from the light source to a progressive direction of the light by the optical element.

### CITATION LIST

### Patent Literature

Patent Literature 1: Japanese Patent Laid-Open No. 2010-238686

### SUMMARY OF INVENTION

### Technical Problem

However, while Patent Literature 1 discloses a structure of the LED module, visibility of light is not increased in a module including a light emitting element and a sensor element.

The present invention has been made in view of such a point, and it is one of objects to provide a flow rate sensor device and a flow rate sensor device equipped with a cover, which include light emitting elements and sensor elements and increase visibility of light.

### Solution to Problem

A flow rate sensor device according to one aspect of the present invention includes a substrate, sensor elements electrically connected to the substrate, light emitting elements positioned in a rear part of the sensor elements and disposed on a surface of the substrate, and light-transmissive cases internally accommodating the light emitting elements between the light-transmissive cases and the substrate. The light-transmissive cases have light diffusion members projecting from ceiling sections toward the light emitting elements, the light diffusion members have light incident surfaces facing the light emitting elements and wall surfaces connecting the light incident surfaces and the ceiling sections, and at least a part of the wall surfaces has a tilting surface having a dimension between the opposing wall surfaces, the dimension gradually increasing from a side close to the light incident surface toward the ceiling section.

### Advantageous Effect of Invention

According to the present invention, visibility of light can be increased in a module including light emitting elements and sensor elements.

### BRIEF DESCRIPTION OF DRAWINGS

FIG. 1 is a perspective view of a flow rate sensor device according to an embodiment.

FIG. 2 is a longitudinal cross section view of the flow rate sensor device according to the embodiment, which is taken along a longitudinal direction of a substrate.

FIG. 3 is a circuit diagram (one example) of the flow rate sensor device according to the embodiment.

FIG. 4 is a perspective view of light-transmissive cases in the flow rate sensor device according to the embodiment.

FIG. 5 is a view from inside of the light-transmissive case according to the embodiment.

FIG. 6A is a longitudinal cross section view of a light-transmissive case part according to the embodiment, which is taken along a direction orthogonal to the longitudinal direction of the substrate.

FIG. 6B is a longitudinal cross section view of the light-transmissive case part according to the embodiment, which is taken along the longitudinal direction of the substrate.

FIG. 7 is a schematic side view of the flow rate sensor device equipped with a cover according to an embodiment.

### DESCRIPTION OF EMBODIMENT

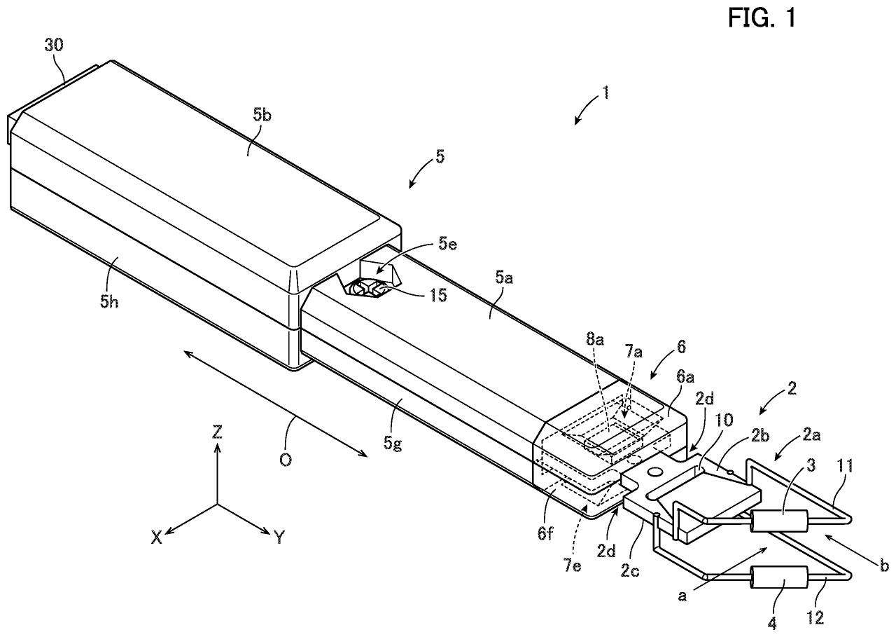

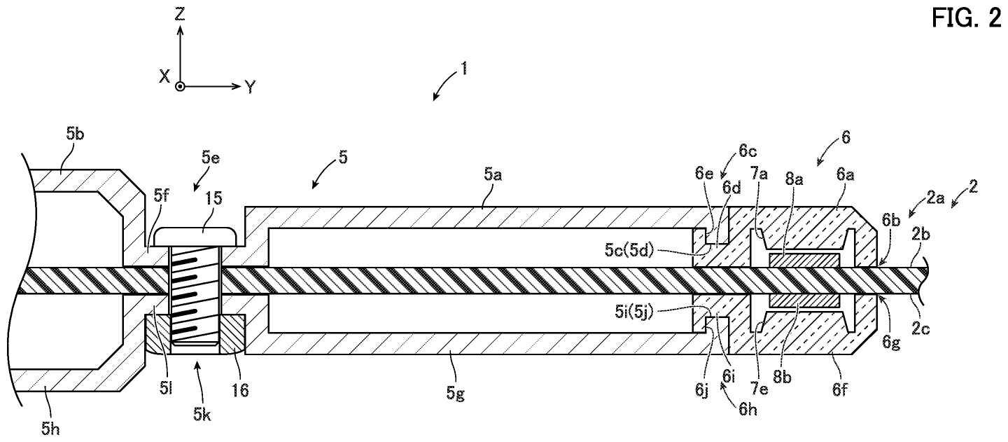

A flow rate sensor device according to an embodiment is described below with reference to attached drawings. FIG. 1 is a perspective view of a flow rate sensor device according to an embodiment. FIG. 2 is a longitudinal cross section view of the flow rate sensor device according to the embodiment, which is taken along a longitudinal direction of a substrate. The term “longitudinal cross section view” herein refers to a cross section view taken along a direction of thickness of a substrate. Although a flow rate sensor is exemplarily described as a sensor device according to an embodiment, a subject of a detection is not particularly limited if the sensor device can detect a change in flow rate. Hereinafter, following description is given by handling sensor elements 3 and 4 as wind speed sensors.

As shown in FIG. 1 and FIG. 2, a flow rate sensor device 1 includes sensor elements 3 and 4 disposed at a tip portion 2a of a substrate 2. A change in flow rate is detected in the sensor elements 3 and 4, and, based on the detection information, light emitting elements 8a and 8b provided on a tip side of the substrate 2 are caused to emit light.

The substrate 2 excluding the tip portion 2a is accommodated within a light-transmissive case 6 and a housing 5, and the tip portion 2a of the substrate 2 projects forward from a tip of the light-transmissive case 6 and is exposed to outside. As shown in FIG. 1, both ends in a width direction (X direction) of the substrate 2 have concave portions 2d. The expression “tip portion 2a” of the substrate 2 refers to a tip side from a part that is narrow in width because of the concave portions 2d.

The substrate 2 has a flat plate shape. While the substrate 2 according to this embodiment has a shape having a longer length dimension in the Y direction than the width dimension in the X direction, the substrate 2 is not limited thereto. The Y direction being a longitudinal direction of the substrate 2 is defined as “axis direction O”. The substrate 2 is an insulating substrate and is not particularly limited but is preferably a general printed board acquired by impregnating glass cloth with an epoxy resin and can be presented as, for example, an FR4 substrate.

A pair of sensor elements 3 and 4 electrically connected to the substrate 2 are disposed in the tip portion 2a of the substrate 2 projecting from the light-transmissive case 6. The sensor elements 3 and 4 are spaced apart toward the front of the substrate 2 along the Y direction, and the sensor elements 3 and 4 and the substrate 2 are connected through lead lines 11 and 12. In addition to the sensor elements 3 and 4, light emitting elements 8a and 8b (FIG. 1 does not show the light emitting element 8b) are disposed in the tip side of the substrate 2, and the light emitting elements 8a and 8b are positioned in a rear part of the sensor elements 3 and 4 and are accommodated within light-transmissive cases 6a and 6f. The sensor elements 3 and 4 and the light emitting elements 8a and 8b are disposed at positions that are close in distance.

For example, the sensor element 3 includes a resistance element 13 for flow rate detection as a thermo-sensitive resistance element. The sensor element 4 includes a resistance element 14 for temperature compensation as a thermo-sensitive resistance element.

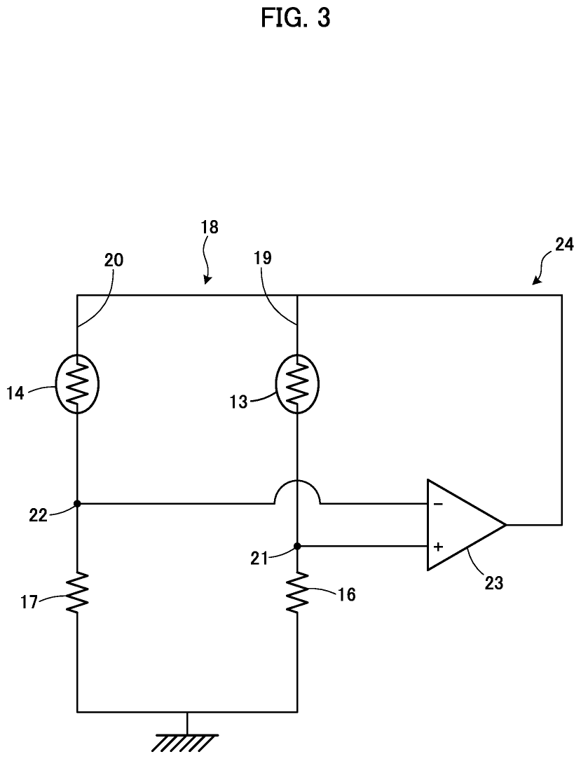

The resistance element 13 for flow rate detection and the resistance element 14 for temperature compensation construct a circuit shown in FIG. 3. As shown in FIG. 3, the resistance element 13 for flow rate detection, the resistance element 14 for temperature compensation and resistors 16 and 17 construct a bridge circuit 18. As shown in FIG. 3, the resistance element 13 for flow rate detection and the resistor 16 construct a first series circuit 19, and the resistance element 14 for temperature compensation and the resistor 17 construct a second series circuit 20. The first series circuit 19 and the second series circuit 20 are connected in parallel to construct the bridge circuit 18.

As shown in FIG. 3, an output unit 21 of the first series circuit 19 and an output unit 22 of the second series circuit 20 are connected to a differential amplifier (amp) 23. A feedback circuit 24 including the differential amplifier 23 is connected to the bridge circuit 18. The feedback circuit 24 includes a transistor (not shown) and so on.

The resistors 16 and 17 have a lower temperature coefficient of resistance (TCR) than those of the resistance element 13 for flow rate detection and the resistance element 14 for temperature compensation. For example, the resistance element 13 for flow rate detection has a predetermined resistance value Rs1 at a heated state controlled so as to have a higher temperature than a predetermined ambient temperature by a predetermined value, and the resistance element 14 for temperature compensation is, for example, controlled so as to have a predetermined resistance value Rs2 at the ambient temperature. It should be noted that the resistance value Rs1 is lower than the resistance value Rs2. The resistor 16 which constructs the first series circuit 19 along with the resistance element 13 for flow rate detection is, for example, a fixed resistor having a resistance value R1 similar to the resistance value Rs1 of the resistance element 13 for flow rate detection. The resistor 17 which constructs the second series circuit 20 along with the resistance element 14 for temperature compensation is, for example, a fixed resistor having a resistance value R2 similar to the resistance value Rs2 of the resistance element 14 for temperature compensation.

The sensor element 3 is set to have a higher temperature than the ambient temperature, and, when the sensor element 3 receives wind, the temperature of the resistance element 13 for flow rate detection which is a heat element decreases. Thus, the potential of the output unit 21 of the first series circuit 19 to which the resistance element 13 for flow rate detection is connected changes. Therefore, a differential output is acquired by the differential amplifier 23. Then, in the feedback circuit 24, driving voltage is applied to the resistance element 13 for flow rate detection based on the differential output. In a microcomputer (not shown), a wind speed can be calculated and output based on a change in voltage required for heating the resistance element 13 for flow rate detection. The microcomputer is, for example, installed on a surface of the substrate 2 within the housing 5 and is electrically connected to the sensor elements 3 and 4 through the lead lines 11 and 12 and a wiring pattern (not shown) on the surface of the substrate 2.

The resistance element 14 for temperature compensation provided in the sensor element 4 detects a temperature of a fluid itself and compensates for an influence of a temperature change of the fluid. In this way, by having the resistance element 14 for temperature compensation, an influence of a temperature change of the fluid on flow rate detection can be reduced, and the flow rate detection can be performed with high precision. As described above, the resistance element 14 for temperature compensation has a sufficiently higher resistance than that of the resistance element 13 for flow rate detection and is set to have a temperature around the ambient temperature. Thus, when the sensor element 4 receives wind, the potential of the output unit 22 of the second series circuit 20 to which the resistance element 14 for temperature compensation is connected does not change greatly. Therefore, a differential output based on a resistance change of the resistance element 13 for flow rate detection can be acquired as a reference potential with high precision.

The circuit configuration shown in FIG. 3 is merely an example, and the circuit configuration is not limited thereto.

According to this embodiment, as shown in FIG. 1, the sensor element 3 and the sensor element 4 are spaced apart from the substrate 2 and diagonally tilt with respect to the axis direction O (Y direction) of the substrate 2. The sensor elements 3 and 4 are disposed so as to tilt with respect to the axis direction O within the XY plane.

In this way, because the sensor element 3 tilts with respect to a lateral direction a parallel to the X direction and a vertical direction b parallel to the axis direction O (Y direction), the sensor element 3 properly touches both of wind in the lateral direction a and wind in the vertical direction b. Therefore, a flow rate of a fluid can be detected with high precision in wind directions of the lateral direction a and the vertical direction b.

As described above, the sensor elements 3 and 4 are preferably spaced apart in a front part of the substrate 2 along the axis direction O (Y direction). In other words, the sensor elements 3 and 4 do not face the substrate 2 in the height direction (Z direction). Thus, turbulence of air flow caused by obstruction of the substrate 2 and the housing 5 can be prevented, the air flow in vicinity of the sensor elements 3 and 4 can be stabilized, and the precision of wind detection can be increased.

Preferably, the sensor element 4 and the sensor element 3 tilt at an equal tilt angle with respect to the axis direction O of the substrate 2 and are spaced apart and face each other in the Z direction. In this way, by disposing the sensor element 3 and the sensor element 4 closely, the temperature change of a fluid, which is observed by the sensor element 4, can be regarded as an ambient temperature of the sensor element 3, and the temperature change of the fluid can be compensated with high precision. Because the sensor element 3 and the sensor element 4 have an equal tilt angle, for example, turbulence of air flow does not easily occur in vicinity of the sensor element 3, and wind can be caused to be abutted uniformly against all of the detection surface of the sensor element 3. Thus, the precision of detection can be increased more effectively.

Although the sensor element 3 and the sensor element 4 preferably tilt at an equal tilt angle with respect to the axis direction O of the substrate 2 and are spaced apart and face each other in the Z direction, the sensor element 4 is only required to be disposed at a position where a temperature change of a fluid can be observed. For example, the sensor element 4 may be disposed at a position facing the substrate 2.

The lead lines (lead terminals) 11 and 12 connected to the sensor elements 3 and 4 are described. The lead lines 11 and 12 are covered by an insulator. Each of the lead line 11 connected to the sensor element 3 and the lead line 12 connected to the sensor element 4 is fixed to the tip portion 2a of the substrate 2. The surfaces on both sides of the tip portion 2a of the substrate 2 have concave-shaped notches, and the lead lines 11 and 12 are fixed to the notches with, for example, an adhesive. A wiring pattern (not shown) is provided on the surface of the substrate 2, and the lead lines 11 and 12 and the wiring pattern are electrically connected. Preferably, the tip portion 2a of the substrate 2 has a plurality of holes, and the lead lines 11 and 12 are inserted into the holes and are connected.

The lead line 11 extends upward from an upper surface (one surface) 2b of the substrate 2 and extends toward the front of the tip portion 2a of the substrate 2 along the Y direction. The lead line 11 is bent at a front position of the tip portion 2a such that the sensor element 3 has a predetermined tilt angle. The lead line 12 extends downward from a lower surface (another surface) 2c of the substrate 2 and further extends toward the front of the tip portion 2a of the substrate 2 along the Y direction. The lead line 12 is bent at a front position of the tip portion 2a such that the sensor element 4 has a tilt angle equal to that of the sensor element 3. In this way, because of the bent lead lines 11 and 12, the sensor elements 3 and 4 can be easily and properly disposed at the equal tilt angle in the front part of the tip portion 2a of the substrate 2 along the Y direction and can be spaced apart in the Z direction.

Since, as described above, the sensor elements 3 and 4 and the substrate 2 are spaced apart and are connected through the lead lines 11 and 12, heat of the sensor elements 3 and 4 can be prevented from being transmitted directly to the substrate 2. Thus, the thermal influence from the sensor elements 3 and 4 can be weakened on the light emitting elements 8a and 8b.

The tip portion 2a of the substrate 2 has a through hole 10. Because of the through hole 10 of the substrate 2, thermal resistance of the substrate 2 can be secured, and a thermal influence from the microcomputer and a light emitting element 8a and 8b, which is described below, disposed on the substrate 2 can be reduced on the sensor elements 3 and 4. Because of the through hole 10, when impact is applied to the flow rate sensor device 1, the impact can be alleviated, and the influence of the impact on the sensor elements 3 and 4 can be weakened.

The light emitting element 8a is disposed on the upper surface 2b of the substrate 2. The light emitting element 8a is positioned in a rear part of the through hole 10. The light emitting element 8b is disposed on the lower surface 2c of the substrate 2. These light emitting elements 8a and 8b are preferably disposed at the same position on the upper and lower surfaces (front and back surfaces) of the substrate 2. These light emitting elements 8a and 8b are covered by a first light-transmissive case 6a and a second light-transmissive case 6f, both of which have transparency, respectively.

For example, an LED may be used as each of the light emitting elements 8a and 8b, and the light emitting elements 8a and 8b are controlled so as to change their indications based on wind detection information from the sensor elements 3 and 4. For example, the light emitting elements 8a and 8b can be controlled such that their luminescent colors change based on a wind speed. Light beams from the light emitting elements 8a and 8b are emitted to outside through the light-transmissive cases 6a and 6f.

The light-transmissive case 6 is positioned in a rear part of the sensor elements 3 and 4 and internally accommodates the light emitting elements 8a and 8b between the light-transmissive case 6 and the substrate 2. The light-transmissive case 6 is divided into the light-transmissive case 6a and the light-transmissive case 6f, and the light-transmissive case 6a covers the upper surface 2b of the substrate 2, and the light-transmissive case 6f covers the lower surface 2c of the substrate 2. Light diffusion members 7a and 7e, which are described below, are provided inside of the light-transmissive cases 6a and 6f. The housing 5 that accommodates the substrate 2 is disposed on a side close to a rear end side of the light-transmissive case 6.

The housing 5 is divided into a first housing (5a, 5b) and a second housing (5g, 5h), and the first housing (5a, 5b) covers the upper surface 2b of the substrate 2, and the second housing (5g, 5h) covers the lower surface 2c of the substrate 2. The first housing (5a, 5b) and the second housing (5g, 5h) have housing front portions 5a and 5g at the front and housing rear portions 5b and 5h at the rear, respectively, and the housing rear portions 5b and 5h are wider in width in the X direction and higher in height in the Z direction than the housing front portions 5a and 5g.

For example, both of the first housing (5a, 5b) and the second housing (5g, 5h) are provided as nontransparent colored cases. Thus, light beams from the light emitting elements 8a and 8b do not pass through the first housing (5a, 5b) and the second housing (5g, 5h) but are emitted to outside from parts of the first light-transmissive case 6a and the second light-transmissive case 6f.

By covering the substrate 2 with the housing 5 and the light-transmissive case 6, the light emitting elements 8a and 8b and an element, not shown, disposed on the substrate 2 can be properly protected from outside.

The first light-transmissive case 6a and the first housing (5a, 5b) and the second light-transmissive case 6f and the second housing (5g, 5h) are disposed on the front and back surfaces of the substrate 2, respectively, with the tip portion 2a of the substrate 2 projecting to outside (where the through hole 10 is also exposed to outside), and, by using a fastening member 15 such as a screw, the substrate 2, the housings (5a, 5b, 5g and 5h) and the light-transmissive cases 6a and 6f are fixed.

As shown in FIG. 2, the light-transmissive cases 6a and 6f have, at their front surfaces, notches 6b and 6g, respectively, for causing a part of the substrate 2 to project forward, and a through hole is formed by the notches 6b and 6g when the light-transmissive cases 6a and 6f are combined. The substrate 2 is inserted through the through hole so that the substrate 2 can be extended from inside of the light-transmissive case 6 to outside of the light-transmissive case 6. Connection portions 6c and 6h to connect to the housing front portions 5a and 5g are provided on the rear surfaces of the light-transmissive cases 6a and 6f. The connection portions 6c and 6h have extension portions 6d and 6i that extend toward the rear part along the substrate 2, and tips of the extension portions 6d and 6i extend in the perpendicular direction with respect to the substrate 2 and form connection concave portions 6e and 6j.

Connection portions 5c and 5i are provided in front parts of the housing front portions 5a and 5g, respectively, and the connection portions 5c and 5i have connection convex portions 5d and 5j which fit into the connection concave portions 6e and 6j. The housing front portions 5a and 5g have recesses 5e and 5k closely to the housing rear portions 5b and 5h, and bottom walls 5f and 5l of the recesses 5e and 5k are in contact with the upper surface 2b and lower surface 2c of the substrate 2. The bottom walls 5f and 5l of the recesses 5e and 5k and the substrate 2 in contact with the bottom walls 5f and 5l have a through hole to which the fastening member 15 is to be inserted. When the bottom walls 5f and 5l of the recesses 5e and 5k are in contact with the upper surface 2b and lower surface 2c of the substrate 2, the connection portions 6c and 6h of the light-transmissive cases 6a and 6f and the connection portions 5c and 5i of the housing front portions 5a and 5g are associated, and the light-transmissive cases 6a and 6f and the housing front portions 5a and 5g are connected to be flush with each other.

The connection convex portions 5d and 5j of the housing front portions 5a and 5g are connected to the connection concave portions 6e and 6j of the light-transmissive cases 6a and 6f, the light-transmissive cases 6a and 6f are covered by the light emitting elements 8a and 8b on the substrate 2, and the position of the through hole of the recesses 5e and 5k and the position of the through hole of the substrate 2 are aligned. Under this condition, the fastening member 15 is inserted from the recess 5e positioned on the upper surface 2b side of the substrate 2 to the through holes of the substrate 2 and the recesses 5e and 5k, and the fastening member 15 is screwed together with a nut part 16 at the recess 5k positioned on the lower surface 2c side of the substrate 2.

Thus, with the tip portion 2a of the substrate 2 projecting from the through hole formed by the notches 6b and 6g of the light-transmissive cases 6a and 6f, the substrate 2 is sandwiched at its front and back surfaces by the light-transmissive case 6 and the housing 5. Then, the substrate 2, the housing 5 and the light-transmissive case 6 are integrally assembled. In this way, because the substrate 2, the light-transmissive case 6 and the housing 5 can be integrally constructed only by using the fastening member 15, the easy assembly and simple construction of the flow rate sensor device 1 can be realized.

External connection terminals 30 for input and for output are provided at the rear end of the flow rate sensor device 1 (see FIG. 1). As the external connection terminals 30, for example, USB terminals having different shapes are used. A plurality of flow rate sensor devices 1 are electrically connected via a communication cable on the external connection terminal 30 sides so that a multiple sensor unit can be configured. The light emitting elements 8a and 8b can emit light at multiple points by using the multiple sensor unit, which is applicable to various applications. For example, the multiple sensor unit can be used as an indoor or outdoor illumination or can be used for analysis of a wind speed.

Here, in the flow rate sensor device 1 according to this embodiment, in order to inform detection information by the sensor elements 3 and 4 with light, the light emitting elements 8a and 8b are caused to emit light. The emitted light from the light emitting elements 8a and 8b including, for example, an LED has a progressive characteristic but has low diffusibility. Accordingly, in this embodiment, the progressive light is diffused in a predetermined direction to improve its visibility.

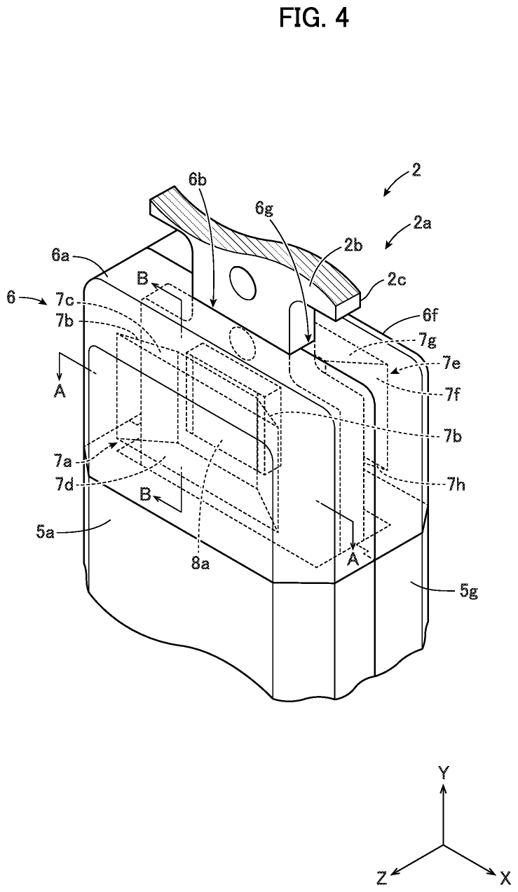

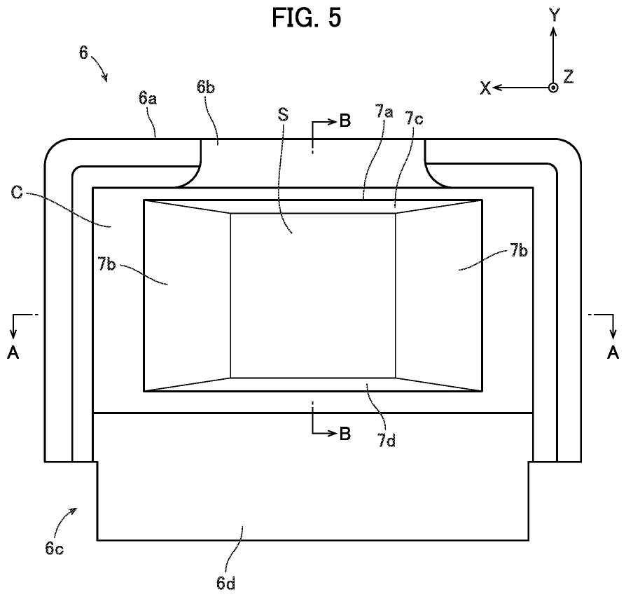

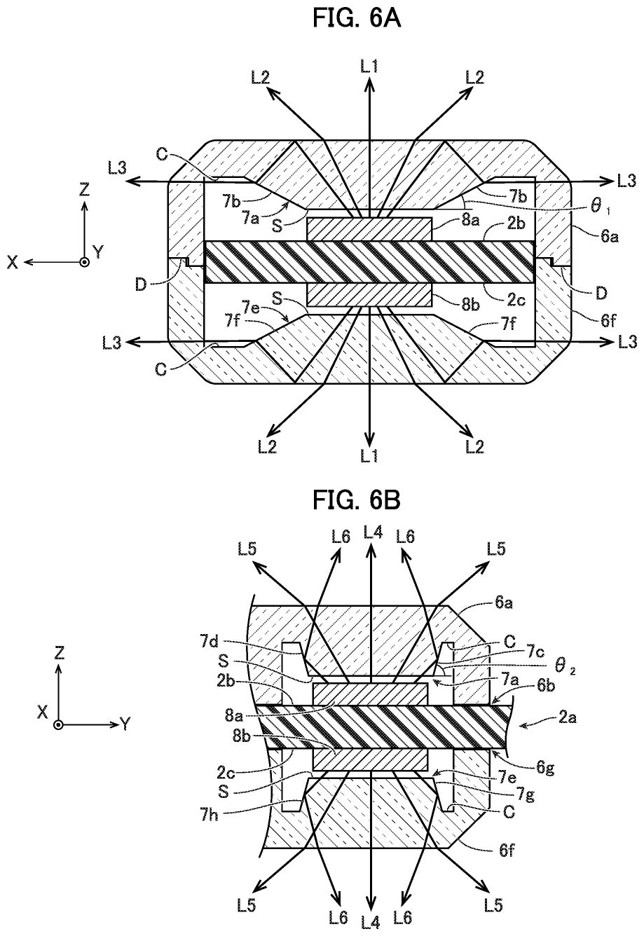

With reference to FIG. 4 to FIG. 6A and FIG. 6B, a configuration of the light diffusion member provided in the light-transmissive case according to this embodiment is described in detail below. FIG. 4 is a perspective view of the light-transmissive case in the flow rate sensor device according to the embodiment. FIG. 5 is a view from inside of the light-transmissive case according to the embodiment. FIG. 6A is a longitudinal cross section view of the light-transmissive case part according to the embodiment, which is taken along a direction orthogonal to the longitudinal direction of the substrate. FIG. 6B is a longitudinal cross section view of the light-transmissive case part according to the embodiment, which is taken along the longitudinal direction of the substrate. In other words, FIG. 6A is a cross section view taken at a line A-A in FIG. 4 and FIG. 5. FIG. 6B is a cross section view taken at a line B-B in FIG. 4 and FIG. 5.

As shown in FIG. 4 and FIG. 6A and FIG. 6B, the light-transmissive cases 6a and 6f are connected to the connection portions 5c and 5i (see FIG. 2) of the housing front portions 5a and 5g at the connection portions 6c and 6h (see FIG. 2) provided on the rear surfaces with the tip portion 2a of the substrate 2 projecting from the notches 6b and 6g provided in the front surface. Here, the light-transmissive cases 6a and 6f accommodate the light emitting elements 8a and 8b disposed closely to the tip of the substrate 2 between the light-transmissive cases 6a and 6f and the substrate 2.

As shown in FIG. 5 and FIGS. 6A and 6B, inside the light-transmissive cases 6a and 6f, light diffusion members 7a and 7e project from ceiling sections C so as to direct toward the light emitting elements 8a and 8b disposed on the substrate 2. Light incident surfaces (opposing surfaces) S facing the light emitting elements 8a and 8b of the light diffusion members 7a and 7e are provided substantially in parallel with radiating surfaces of the light emitting elements 8a and 8b. The light incident surfaces S preferably have an area equal to or larger than that of the radiating surfaces of the light emitting elements 8a and 8b. Thus, light radiated from the light emitting elements 8a and 8b can be effectively introduced to the light diffusion members 7a and 7e so that the efficiency of light input to the light diffusion members 7a and 7e can be increased. Referring to FIG. 6A and 6B, the light emitting elements 8a and 8b disposed on the substrate 2 and the light diffusion members 7a and 7e are spaced apart. In other words, spaces are provided between the radiating surfaces of the light emitting elements 8a and 8b and the light incident surfaces S of the light diffusion members 7a and 7e. However, the radiating surfaces of the light emitting elements 8a and 8b and the light incident surfaces S of the light diffusion members 7a and 7e may be in contact if emitted light beams from the light emitting elements 8a and 8b can be diffused through the light diffusion members 7a and 7e. Although FIG. 5 shows the first light-transmissive case 6a, the second light-transmissive case 6f has the same shape.

The light diffusion members 7a and 7e have side wall surfaces 7b and 7f, respectively, which connect the light incident surfaces S and the ceiling section C, on both sides in the lateral direction (X direction) orthogonal to the longitudinal direction (Y direction) of the substrate 2, and the side wall surfaces 7b and 7f have tilting surfaces having dimensions in the lateral direction (X direction) between the side wall surfaces 7b and 7f increases gradually from sides close to the light incident surfaces S to the ceiling sections C.

As shown in FIG. 4, FIG. 5 and FIG. 6B, the light diffusion members 7a and 7e have front wall surfaces 7c and 7g and rear wall surfaces 7d and 7h, respectively, on the both sides in the vertical direction that is the longitudinal direction (Y direction) of the substrate 2. The dimensions in the vertical direction (Y direction) between the front wall surfaces 7c and 7g and the rear wall surfaces 7d and 7h are gradually widen from sides close to the light incident surface S to the ceiling sections C, from this the front wall surfaces 7c and 7g and the rear wall surfaces 7d and 7h have tilting surfaces. However, as shown in FIG. 5, FIG. 6A and FIG. 6B, the front wall surfaces 7c and 7g and the rear wall surfaces 7d and 7h have tilting surfaces having a steeper angle than those of the side wall surfaces 7b and 7f. Alternatively, the front wall surfaces 7c and 7g and the rear wall surfaces 7d and 7h may have perpendicular surfaces, not shown, with respect to the light incident surfaces S. Here, as shown in FIG. 6A, the tilt angles of the side wall surfaces 7b and 7f are provided by an angle θ₁ between the extension lines of the light incident surfaces S and the side wall surfaces 7b and 7f, and the tilt angle θ₁ is preferably, for example, 45° and is preferably equal to the directivity angles of the light emitting elements 8a and 8b. As shown in FIG. 6B, the tilt angles of the front wall surfaces 7c and 7g and the rear wall surfaces 7d and 7h are provided by an angle θ₂ between the extension lines of the light incident surfaces S and the front wall surfaces 7c and 7g and the rear wall surface 7d and 7h, and a relationship of tilt angle θ₂>tilt angle θ₁ is satisfied. The tilt angle θ₂ is, for example, preferably, equal to or larger than 45° and is an angle larger than the directivity angles of the light emitting elements 8a and 8b.

The light-transmissive cases 6a and 6f are preferably transparent and are formed by a material such as a thermoplastic resin such as an acrylic resin or a polycarbonate-based resin or glass. The light-transmissive cases 6a and 6f and the light diffusion members 7a and 7e are formed by the same member according to this embodiment, but they may be formed by different members. The light-transmissive cases 6a and 6f may be, for example, translucent instead of transparent because the light-transmissive cases 6a and 6f are only required to allow light to pass through.

Next, with reference to FIG. 6A and FIG. 6B, light diffusion operations by the light diffusion members 7a and 7e are described. As shown in FIG. 6A, on the tip side of the substrate 2, the light emitting elements 8a and 8b are disposed at the same positions on the upper and lower surfaces 2b and 2c of the substrate 2. The light-transmissive cases 6a and 6f are disposed so as to cover the light emitting elements 8a and 8b from the upper and lower surfaces 2b and 2c of the substrate 2 and are combined on both sides in the width direction (X direction) of the substrate 2. In this way, on the sides of the substrate 2, steps D at tips of the light- transmissive cases 6a and 6f are associated to prevent the light-transmissive cases 6a and 6f from being displaced from each other (see FIG. 6A). The light-transmissive cases 6a and 6f have the light diffusion members 7a and 7e projecting from the ceiling section C toward the light emitting elements 8a and 8b. Both sides in the lateral direction (X direction) orthogonal to the longitudinal direction (Y direction) of the substrate 2 of the light diffusion members 7a and 7e have side wall surfaces 7b and 7f which gradually widen from the sides close to the light emitting elements 8a and 8b toward the ceiling section C.

Emitted light beams from the light emitting elements 8a and 8b are input to the light diffusion members 7a and 7e. Light beams L1 to L6 having a high progressive characteristic (directivity) and low diffusibility are repeatedly refracted within the light diffusion members 7a and 7e, and diffused light is output from the front surfaces and side surfaces of the light-transmissive cases 6a and 6f to outside. FIG. 6A and FIG. 6B schematically show states of the light beams L1 to L6 in the light diffusion members 7a and 7e.

As shown in FIG. 6A, parts of the light beams L1 which are radiated perpendicularly (in the top-bottom direction shown in FIG. 6A) from the radiating surfaces of the light emitting elements 8a and 8b travel straight ahead in the Z direction and are output from the light-transmissive cases 6a and 6f. On the other hand, the light beams L2 the input angle of which does not satisfy the critical angles of the light diffusion members 7a and 7e with respect to the air of the light beams L2 and L3 input in a tilted manner to the light incident surfaces S of the light diffusion members 7a and 7e are refracted from the surfaces of the light-transmissive cases 6a and 6f and are output to outside. The light beams L3 the input angle of which exceeds the critical angles of the light diffusion members 7a and 7e are reflected within the light-transmissive cases 6a and 6f, are then refracted and are output from the light-transmissive cases 6a and 6f to outside. Here, when parts of the light beam L3 reflected within the light-transmissive cases 6a and 6f reach the side wall surfaces 7b and 7f being tilting surfaces, the parts of the light beam L3 pass in the substantially lateral direction (substantial X direction), and the light beams are therefore output also from the side surfaces of the light-transmissive cases 6a and 6f. In this way, the light beams L2 and L3 from the light emitting elements 8a and 8b have spread in the X direction because of the light diffusion members 7a and 7e so that the progressive light can have diffusibility. Particularly, according to this embodiment, the light beams from the light emitting elements 8a and 8b can be caused to be output to outside from not only the front surfaces but also the side surfaces of the light-transmissive cases 6a and 6f. Thus, the visibility of the light can be improved.

As shown in FIG. 6B, the light-transmissive cases 6a and 6f are connected to the housing front portions 5a and 5g at their rear surfaces through the connection portions 6c and 6h with the tip portion 2a (see FIG. 1) of the substrate 2 projecting forward from the notches 6b and 6g in the front surfaces of the light-transmissive cases 6a and 6f (see FIG. 2). On both sides in the vertical direction being the longitudinal direction (Y direction) of the substrate 2 of the light diffusion members 7a and 7e provided in the light-transmissive cases 6a and 6f, the front wall surfaces 7c and 7g and rear wall surfaces 7d and 7h are provided which gradually widen from sides close to the light emitting elements 8a and 8b toward the ceiling sections C and have a steeper tilt than that of the side wall surfaces 7b and 7f. As described above, the front wall surfaces 7c and 7g and the rear wall surfaces 7d and 7h are only required to be surfaces perpendicular to the light incident surfaces S.

Parts of the light beams L4 which are radiated perpendicularly from the radiating surfaces of the light emitting elements 8a and 8b and which are input perpendicularly from the light emitting elements 8a and 8b to the light incident surfaces S of the light diffusion members 7a and 7e travel straight ahead in the Z direction and are output from the front surfaces of the light-transmissive cases 6a and 6f. The light beams L5 the input angles of which does not satisfy the critical angles of the light diffusion members 7a and 7e with respect to the air of the light beams L5 and L6 input in a tilting manner to the light incident surfaces S of the light diffusion members 7a and 7e are refracted by and output from the surfaces of the light-transmissive cases 6a and 6f. The light beams L6 are reflected by the front wall surfaces 7c and 7g and the rear wall surfaces 7d and 7h of the light diffusion members 7a and 7e and are output from the surfaces of the light-transmissive cases 6a and 6f. The tilts of the front wall surfaces 7c and 7g and the rear wall surfaces 7d and 7h are steeper in FIG. 6B than those in FIG. 6A, the light beams reflected within the light-transmissive cases 6a and 6f do not easily pass through in the substantial front-rear direction (Y direction) even though the light beams reach the front wall surfaces 7c and 7g and the rear wall surfaces 7d and 7h, and, in FIG. 6B, the light beams are output to outside from the surfaces of the light-transmissive cases 6a and 6f.

In this way, according to this embodiment, the light beams from the light emitting elements 8a and 8b can be mainly output from the surfaces of the light-transmissive cases 6a and 6f and the lateral direction to outside.

In the manner described above, because of the side wall surfaces 7b and 7f of the light diffusion members 7a and 7e which gradually widen from the sides close to the light emitting elements 8a and 8b toward the ceiling sections C, light can be diffused at predetermined angles in the progressive direction (Z direction) of the output light from the light emitting elements 8a and 8b and in the lateral direction (X direction) orthogonal to the longitudinal direction (Y direction) of the substrate 2. Particularly, because the spread in the Y direction of the light can be suppressed because of the front wall surfaces 7c and 7g and the rear wall surfaces 7d and 7h having steeper tilts than those of the side wall surfaces 7b and 7f or having perpendicular surfaces, the light from the light emitting elements 8a and 8b are diffused at a larger angle than the vertical direction (Y direction) being the longitudinal direction of the substrate 2 toward the lateral direction (X direction) orthogonal to the longitudinal direction (Y direction) of the substrate 2. Thus, particularly, according to this embodiment, the light can be diffused in the lateral direction (X direction), and the intensity of the output light in the lateral direction can be increased, and, at the same time, compared with conventional technologies, the direction of diffusion of the light can be increased, which can improve the visibility of the light.

As described above, the flow rate sensor device 1 according to this embodiment includes the substrate 2, the sensor elements 3 and 4 electrically connected to the substrate 2, the light emitting element 8a disposed on a surface of the substrate 2 in a rear part of the sensor elements 3 and 4, and the light-transmissive case 6a internally accommodating the light emitting element 8a between the light-transmissive case 6a and the substrate 2.

According to this embodiment, the light-transmissive case 6a has the light diffusion member 7a projecting from the ceiling section C toward the direction of the light emitting element 8a. The light diffusion member 7a has the light incident surface S facing the light emitting element 8a and wall surfaces connecting between the light incident surface S and the ceiling section C. At least a part of the wall surfaces has a tilting surface in which a dimension between the opposing wall surfaces gradually increases from sides close to the light incident surface S toward the ceiling section C. Here, the expression “at least a part of the wall surfaces” refers to one of the side wall surfaces 7b, the front wall surface 7c and the rear wall surface 7d included in the light diffusion member 7a in the structure shown in FIG. 5. For example, the dimension between the side wall surfaces 7b gradually increases from sides close to the light incident surface S toward the ceiling section C, or the dimension between the front wall surface 7c and the rear wall surface 7d gradually increases from sides close to the light incident surface S toward the ceiling section C.

With this configuration, light from the light emitting element 8a can be output by externally diffusing the light from the front surface of the light-transmissive case 6a to the side surfaces. Therefore, even when the light emitting element 8a having a high progressive characteristic like an LED is used, the diffusibility can be improved through the light-transmissive case 6a, which can improve the visibility of light.

In the configuration described above, the tilting surfaces provided in parts of the wall surfaces have a gentler tilt angle than those of the other wall surfaces. In this way, light can be diffused through the wall surfaces having gentle tilting surfaces toward sides of the light-transmissive case.

Furthermore, according to this embodiment, the light emitting element 8a can be disposed in vicinity of the sensor elements 3 and 4. Thus, a change in flow rate in vicinity of the light emitting element 8a can be optically indicated with high precision. By disposing the sensor elements 3 and 4 in a front part of the substrate 2 and disposing the light emitting element 8a in a rear part of the sensor elements 3 and 4, the precision of detection by the sensor elements 3 and 4 can be maintained, and, at the same time, the optical indication is properly enabled. In other words, the sensor elements 3 and 4 can be isolated in a front part of the substrate 2 as shown in FIG. 1, and the sensor elements 3 and 4 are disposed away from the substrate 2 so that, for example, turbulence of the air flow can be suppressed and that the precision of detection by the sensor elements 3 and 4 can be increased. In addition, the light emitting element 8a can be disposed at a position which does not disturb the detection by the sensor elements 3 and 4, and the precision of detection by the sensor elements 3 and 4 and proper optical indication are enabled.

According to this embodiment, the side wall surfaces 7b of the light diffusion member 7a disposed on both sides in the lateral direction (X direction) orthogonal to the direction (the axis direction O shown in FIG. 1) of the alignment of the sensor elements 3 and 4 and the light emitting element 8a preferably have tilting surfaces. Thus, light from the light emitting element 8a can be output to outside by diffusing the light in the lateral direction from the surface of the light-transmissive case 6a. As shown in FIG. 1, the sensor elements 3 and 4 are disposed in a front part of the light emitting element 8a, and the housing 5 is disposed in a rear part thereof. Thus, by diffusing light in the lateral direction rather than diffusion in the front-rear direction, failures of the light diffusion can be suppressed, and the light diffusibility can be improved, which can effectively improve the visibility of the light.

According to this embodiment, the light diffusion member 7a has the front wall surface 7c and the rear wall surface 7d on both sides in the vertical direction being the longitudinal direction (axis direction O) of the substrate 2. Each of the front wall surface 7c and the rear wall surface 7d is formed by a perpendicular surface or a tilting surface having a dimension in the vertical direction between the front wall surface 7c and the rear wall surface 7d, which gradually increases from a side close to the light incident surface S toward the ceiling section C. However, the tilting surfaces of the front wall surface 7c and the rear wall surface 7d are steeper than the tilting surface of the side wall surfaces 7b.

Thus, light that diffuses in the front-rear direction can be suppressed, and, at the same time, light can be diffused in the lateral direction, which can increase the intensity of the diffused light in the lateral direction. In this way, by changing the tilting angle and with the simple configuration, light diffused in the front-rear direction can be weakened, and diffusion of light in the lateral direction can be promoted.

According to this embodiment, the sensor elements 3 and 4 are spaced apart in a front part of the substrate 2, and the sensor elements 3 and 4 and the substrate 2 are preferably connected by the lead lines 11 and 12. In this way, by connecting the sensor elements 3 and 4 by using the lead lines 11 and 12, the sensor elements 3 and 4 can be easily and securely spaced apart in a front part of the substrate 2.

According to this embodiment, the substrate 2 has an elongated shape, and the light emitting element 8a is disposed on the tip side of the substrate 2 along with the sensor elements 3 and 4, and the light emitting element 8a is positioned in a rear part of the sensor elements 3 and 4. The light emitting element 8a is accommodated in the light-transmissive case 6a.

In this way, by using the elongated substrate 2, the light emitting element 8a and the sensor elements 3 and 4 can be reasonably disposed in the front-rear direction also in the flow rate sensor device 1 having a reduced size.

According to this embodiment, the housing 5 is provided which is positioned on a rear end side of the light-transmissive case 6a and accommodates the substrate 2. The light-transmissive case 6a has the notch 6b from which a part of the substrate 2 is projected to the front and has, at its rear surface, the connection portion 6c to be connected to the housing 5. Thus, the substrate 2 can be projected to the front of the light-transmissive case 6a, and the light-transmissive case 6a can be properly connected to the subsequently positioned housing 5 so that the substrate 2, the light-transmissive case 6a and the housing 5 can be integrated. In fact, as shown in FIG. 1, the housing 5 has the first housing (5a, 5b) and the second housing (5g, 5h), and the light-transmissive cases 6a and 6f are also disposed in the top-bottom direction through the substrate 2. Thus, by sandwiching the upper and lower parts of the substrate 2 by the first housing (5a, 5b), the second housing (5g, 5h) and the light-transmissive cases 6a and 6h, the integral construction can be realized with the simple configuration.

As shown in FIG. 2 and so on, the light emitting elements 8a and 8b are preferably disposed on the front and back surfaces of the substrate 2. By forming the light emitting elements 8a and 8b on both surfaces of the substrate 2, an optical indicator unit can be provided on both surfaces of the substrate 2. In this way, light decoration can be provided not only on the front surface but also on the back surface of the flow rate sensor device 1, and control can also be performed so as to provide different light decorations (such as different luminescent colors) on the front surface and the back surface.

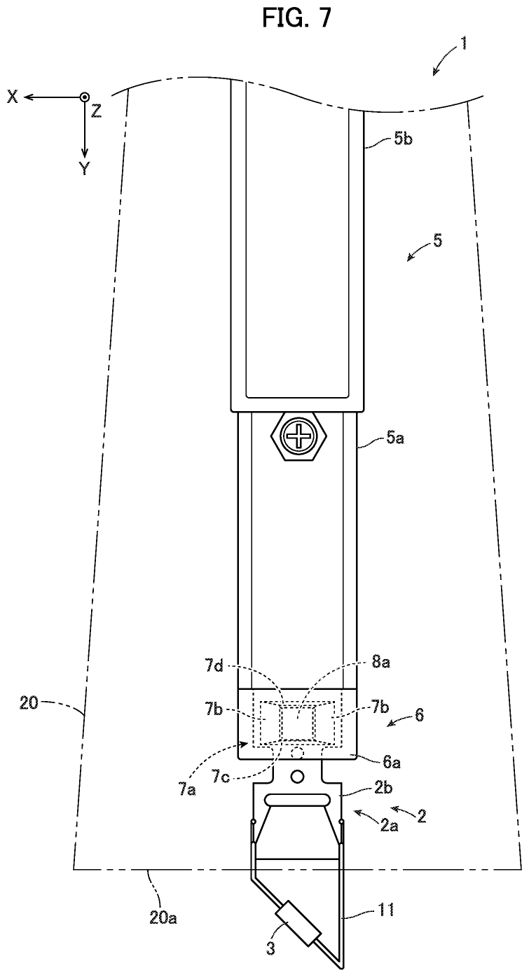

FIG. 7 is a schematic side view of the flow rate sensor device equipped with a cover according to an embodiment.

As shown in FIG. 7, the flow rate sensor device 1 is covered with a cover 20 having an opening portion 20a on its lower side with the sensor elements 3 and 4 facing downward (the sensor element 4 is not shown).

According to this embodiment, the shape of the cover 20 is not limited, but the cover 20 has, for example, a truncated cone shape that widens downward as shown in FIG. 7. An upper part of the cover 20 along with the flow rate sensor device is fixed with a support plate (not shown).

The cover 20 is only required to be light transmissive and may be either transparent or translucent and may have any light transmittance. Various light transmittances and materials can be selected for use in the cover 20 in accordance with the use purpose. Examples of the material of the cover 20 include a thermoplastic resin such as an acrylic resin or a polycarbonate-based resin.

As shown in FIG. 7, the sensor elements 3 and 4 project downward from the opening portion 20a of the cover 20.

Thus, without block of the wind by the cover 20, wind can be detected by the sensor elements 3 and 4, and the light emitting elements 8a and 8b can be caused to emit light. According to this embodiment, as described above, light from the light emitting elements 8a and 8b is diffused through the light-transmissive cases 6a and 6f. The diffused light output from the light-transmissive cases 6a and 6f passes through the cover 20 and is output to outside of the cover 20.

According to this embodiment, the light from the light emitting elements 8a and 8b can be diffused in the lateral direction from the surfaces of the light-transmissive cases 6a and 6f. Thus, the quantity of light leaking from a lower part of the cover 20 can be reduced, and a wide range around the cover 20 can be shined, which can improve the visibility of the light.

The cover 20 also functions as a protection against rain. Therefore, the flow rate sensor device equipped with the cover according to this embodiment can also be used outdoors.

As shown in FIG. 7, the cover 20 has a truncated cone shape that widens downward.

Having described that the cover 20 has a truncated cone shape, the cover 20 can have a cone shape. In order to effectively protect the sensor elements 3 and 4 projecting from the cover 20 from rain moving on the outside of the cover 20, the circumferential surface of the cover 20 is preferably a tilting surface that widens downward like a truncated cone shape or a cone shape, but the circumferential surface may be a perpendicular surface. Also, the cover 20 is preferably transparent or translucent.

According to this embodiment, the opening portion 20a of the cover 20 is preferably closed with a foreign-matter intrusion prevention net. For example, the foreign-matter intrusion prevention net is a mesh material as an insect repellent net. By disposing an insect repellent net over the opening portion 20a, intrusion of insects to inside of the cover 20 can be prevented even during outdoor use, and problems such as occurrence of a failure can be suppressed.

Having described that the sensor elements 3 and 4 are wind speed sensors, the sensor elements 3 and 4 may be any sensor that can detect a gas flow or a change in flow speed of liquid such as water instead of wind speeds.

### INDUSTRIAL APPLICABILITY

As described above, the present invention enables disposition of a sensor element and a light emitting element, can be applied to various applications as indication forms by using flow rate detection and can also be applied for analysis.

The subject application is based on Japanese Patent Application No. 2019-005735 filed Jan. 17, 2019, the entirety of which is incorporated herein.

1. A flow rate sensor device comprising a substrate, sensor elements electrically connected to the substrate, light emitting elements positioned in a rear part of the sensor elements and disposed on a surface of the substrate, and light-transmissive cases internally accommodating the light emitting elements between the light-transmissive cases and the substrate, wherein
the light-transmissive cases have light diffusion members projecting from ceiling sections toward the light emitting elements,
the light diffusion members have light incident surfaces facing the light emitting elements and wall surfaces connecting the light incident surfaces and the ceiling sections, and
at least a part of the wall surfaces has a tilting surface having a dimension between the opposing wall surfaces, the dimension gradually increasing from a side close to the light incident surface toward the ceiling section.

2. The flow rate sensor device according to claim 1, wherein side wall surfaces of the light diffusion members disposed on both sides in a lateral direction orthogonal to a direction of alignment of the sensor elements and the light emitting elements are the tilting surfaces.

3. The flow rate sensor device according to claim 2, wherein the light diffusion members have a front wall surface and a rear wall surface on both sides in a vertical direction being a longitudinal direction of the substrate, and each of the front wall surface and the rear wall surface is a perpendicular surface or a tilting surface having a dimension in the vertical direction between the front wall surface and the rear wall surface, the dimension gradually increases from a side close to the light emitting element to the ceiling section, and the tilting surface has a steeper tilt than that of the side wall surfaces.

4. The flow rate sensor device according to claim 1, wherein the sensor elements are spaced apart in a front part of the substrate, and the sensor elements and the substrate are connected by lead lines.

5. The flow rate sensor device according to claim 1, wherein the light emitting elements and the sensor elements are disposed on a tip side of the substrate, and the light emitting elements are positioned in a rear part of the sensor elements and are accommodated in the light-transmissive cases.

6. The flow rate sensor device according to claim 5, further comprising a housing being positioned on a rear end side of the light-transmissive cases and accommodating the substrate,
wherein the light-transmissive cases have a front surface having a notch from which a part of the substrate projects forward and a rear surface having a connection portion to be connected to the housing.

7. The flow rate sensor device according to claim 1, wherein the light emitting elements are disposed on front and back surfaces of the substrate.

8. A flow rate sensor device equipped with a cover comprising the flow rate sensor device and the cover having an opening portion on a lower side, wherein
the flow rate sensor device has a substrate, sensor elements electrically connected to the substrate, light emitting elements positioned in a rear part of the sensor elements and disposed on a surface of the substrate, and light-transmissive cases internally accommodating the light emitting elements between the light-transmissive cases and the substrate, the light-transmissive cases have light diffusion members projecting from ceiling sections toward the light emitting elements, the light diffusion members have light incident surfaces facing the light emitting elements and wall surfaces connecting the light incident surfaces and the ceiling section, and at least a part of the wall surfaces has a tilting surface having a dimension between the opposing wall surfaces, the dimension gradually increasing from a side close to the light incident surface toward the ceiling section, and
the flow rate sensor device is accommodated within the cover such that the sensor elements face downward and are exposed from the opening portion.

9. The flow rate sensor device equipped with the cover according to claim 8, wherein the opening portion is closed with a foreign-matter intrusion prevention net.

10. The flow rate sensor device or the flow rate sensor device equipped with the cover according to claim 1, wherein the sensor elements are a wind speed sensor that detects a wind speed.
